(19) United States
(12) Patent Application Publication
(10) Pub. No.: US 2024/0150166 A1
(43) Pub. Date: May 9, 2024

(54) Encapsulated MEMS Switching Element, Device and Production Method

(71) Applicant: Siemens Aktiengesellschaft, München (DE)

(72) Inventors: Oliver Raab, Ortenburg (DE); Markus Schwarz, München (DE); Jörg Zapf, München (DE); Hans Santos Wilke, Parsdorf (DE)

(73) Assignee: Siemens Aktiengesellschaft, München (DE)

(21) Appl. No.: 18/548,551

(22) PCT Filed: Feb. 21, 2022
(86) PCT No.: PCT/EP2022/054214

§ 371 Date: Aug. 31, 2023

(30) Foreign Application Priority Data
Mar. 11, 2021 (EP) 21161930.9

(51) Int. Cl. B81B 7/00; B81C 1/00; H01H 1/00

(52) U.S. Cl. CPC B81B 7/0041; B81C 1/00269; H01H 1/0036; B81B 2201/014; H01H 2001/0084

(57) ABSTRACT

Various embodiments include a microelectromechanical switching element. The element may include: a substrate with a carrier layer, an electrically insulating layer, and a semiconductor layer; a deflectable bending element formed by a freed subregion of the semiconductor layer; and a cover substrate connected to the carrier substrate. The carrier layer defines a first cutout in the region of the bending element. The cover substrate comprises a second cutout and/or an encircling spacer layer in the region of the bending element. The first cutout and the second cutout define a superordinate hollow space in which the bending element is arranged so as to be deflectable. The superordinate hollow space is delimited by the carrier layer and by the cover substrate to provide a hermetically encapsulation from the external environment.

### CROSS-REFERENCE TO RELATED APPLICATIONS

This application is a U.S. National Stage Application of International Application No. PCT/EP2022/054214 filed Feb. 21, 2022, which designates the United States of America, and claims priority to EP Application No. 21161930.9 filed Mar. 11, 2021, the contents of which are hereby incorporated by reference in their entirety.

### TECHNICAL FIELD

The present disclosure relates to switches. Various embodiments of the teachings herein include microelectromechanical switching elements and/or methods for producing such a switching element.

### BACKGROUND

Microelectromechanical switching elements are referred to as MEMS switching elements. These are mechanical solid-state switching elements which are structured in the micrometer to nanometer range and comprise electrostatically actuated bending elements, such that they can be switched by changing an electrical voltage. A plurality of such individual MEMS switches are often arranged so as to form an array, in particular in order to achieve a sufficiently great current carrying capacity and/or dielectric strength.

Such MEMS switches and switching apparatuses based thereon are described, for example, in DE 10 2017 215 236 A1 and WO 2018 028 947 A1. The subject matter of DE102017215236A1 is an MEMS switch which is constructed on a silicon-on-insulator substrate (SOI substrate). With this manufacturing technology, the predefined switching times can be set particularly precisely on account of the mature and reproducible production processes. The bending element is freed by means of subtractive manufacturing, the SOI substrate being processed on both sides (top and bottom). Here, the carrier layer of the SOI substrate is removed from the rear side of the substrate completely in the region of the bending beam, such that a deflection of the bending beam in a vertical direction is made possible. A cover substrate is typically arranged on the front side of the SOI substrate (the side with the bending element), said cover substrate also comprising a cutout in the region of the bending beam. A control electrode and one or more mating contacts for the switching process may be arranged in this region of the cover substrate.

A disadvantage of these known SOI MEMS switches is that, due to the processing of the SOI substrate from both sides, damage to the active silicon layer can occur relatively easily during production. A further disadvantage is that the bending element is initially not protected against chemical and mechanical environmental influences owing to the exposed rear side. Although it is fundamentally possible to encapsulate such an SOI MEMS switch in a superordinate housing, this requires further manufacturing steps, and a relatively large component is produced, which requires a correspondingly large amount of installation space in a superordinate apparatus.

Other types of MEMS switching elements may include metal bending beams. Typically, however, the desired predetermined switching properties are less precisely settable with this technology.

Here, too, the encapsulation with a separate housing is usually necessary for protection against external environmental influences, which also leads to comparatively large dimensions.

### SUMMARY

The teachings of the present disclosure may provide a switching element which overcomes the mentioned disadvantages. For example, some embodiments include a microelectromechanical switching element (1), comprising: a multi-layer carrier substrate (100) comprising a first layer (110) serving as carrier layer, an electrically insulating second layer (120) and a third layer (130) configured as semiconductor layer, a deflectable bending element (135) which is formed by a freed subregion of the semiconductor layer (130), and an areal cover substrate (200) which is connected to the carrier substrate (100), wherein the carrier substrate (100) and in particular the carrier layer (110) thereof comprises a cutout (150) in the region of the bending element (135), and wherein the cover substrate (200) also comprises a cutout (250) and/or an encircling spacer layer (260) in the region of the bending element (135), such that a superordinate hollow space (350) is formed overall, in which the bending element (135) is arranged so as to be deflectable, wherein the superordinate hollow space (350) is delimited by the carrier layer (110) and by the cover substrate (200) in such a way that it is hermetically encapsulated toward the external environment, wherein the multi-layer carrier substrate (100) is a silicon-on-insulator layer system.

In some embodiments, the deflection direction (r) of the bending element (135) is oriented substantially perpendicularly with respect to the layer plane of the multi-layer carrier substrate (100).

In some embodiments, the cutout (150) in the carrier layer (110) is formed by a prefabricated cavity in the silicon-on-insulator layer system (100).

In some embodiments, the hermetic encapsulation of the superordinate hollow space (350) is effected by a permanent, fluid-tight, areal connection (270) between the multi-layer carrier substrate (100) and the cover substrate (200).

In some embodiments, the cover substrate (200) is configured functionally as electrically insulating cover substrate and is in particular formed substantially of glass or silicon.

In some embodiments, a switching contact (140) is arranged on the bending element (135) and wherein the cover substrate (200) bears at least one mating contact (240) which is able to be contacted with the switching contact (140) of the bending element (135) in dependence on a deflection of the bending element (135).

the cover substrate (200) comprises a control electrode (210) which can be used to influence the deflection of the bending element (135).

As another example, some embodiments include an apparatus comprising a microelectromechanical switching element (1) or an array of multiple microelectromechanical switching elements (1) as described herein.

In some embodiments, the apparatus is configured as a switching apparatus, as a converter or inverter, as a logic circuit and/or as a logic gate.

In some embodiments, the apparatus is configured as a surface-mountable component.

In some embodiments, the cover substrate (200) and/or the carrier substrate (100) comprises one or more leadthroughs (400) for electrical contacting of the at least one switching element (1).

As another example, some embodiments include a method for producing a switching element (1) as described herein, wherein a) a prefabricated multi-layer carrier substrate (100) with a prefabricated cavity (150) in the first carrier layer (110) is used, b) the bending element (135) is freed from this prefabricated carrier substrate (100) by subtractive manufacturing, and, c) in a wafer bonding step, the cover substrate (200) is permanently connected to the carrier substrate (100), as a result of which the superordinate hollow space (350) is hermetically encapsulated, wherein the multi-layer carrier substrate (100) is a silicon-on-insulator layer system.

In some embodiments, the subtractive manufacturing in step b) is effected by processing the multi-layer carrier substrate (100) exclusively on one side.

### BRIEF DESCRIPTION OF THE DRAWINGS

The teachings of the present disclosure are described below on the basis of some exemplary embodiments with reference to the appended drawings, in which:

FIG. 1 shows a schematic cross-sectional illustration of a switching element according to the prior art;

FIG. 2 shows a schematic top view of a further known switching element;

FIG. 3 shows a schematic sectional illustration of a conventional switching element with a housing;

FIGS. 4 to 6 show a plurality of process stages in the production of a switching element incorporating teachings of the present disclosure;

FIG. 7 shows a prefabricated carrier substrate for producing a switching element incorporating teachings of the present disclosure; and

FIG. 8 shows another example switching element incorporating teachings of the present disclosure.

In the figures, identical or functionally identical elements are provided with the same reference designations.

### DETAILED DESCRIPTION

In particular, the teachings of the present disclosure to provide a switching element which is robust with respect to external environmental influences and which can simultaneously be designed in as compact a manner as possible. In particular, the aim is for it to also be possible to set the predefined switching properties in as precise a manner as possible. An example microelectromechanical switching element incorporating teachings of the disclosure comprises a multi-layer carrier substrate comprising a first layer serving as carrier layer, an electrically insulating second layer, and a third layer configured as semiconductor layer. The switching element comprises a bending element which is formed by a freed subregion of the semiconductor layer (that is to say of the third layer).

Furthermore, the switching element comprises an areal cover substrate which is connected to the multi-layer carrier substrate. In this case, the carrier substrate, in particular the carrier layer thereof, comprises a cutout in the region of the bending element. Furthermore, the cover substrate also comprises either a cutout and/or a spacer layer which runs in encircling fashion around the region of the bending element in the region of the bending element, such that the cooperation of the two cutouts or of the one cutout and the encircling spacer layer forms a superordinate hollow space overall, in which the bending element is arranged so as to be deflectable. This superordinate hollow space is delimited by the carrier layer and the cover substrate in such a way that it is hermetically encapsulated toward the external environment.

A microelectromechanical switching element means a switching element which is produced by microsystems technology means. The term microsystems technology is understood broadly to mean the technology which is capable of producing microscopically small mechanically operative component parts which can perform a movement, for example switches or gears. In the broader sense, the term microsystems technology should also include nanosystems technology, which makes corresponding structures in the submicrometer to nanometer range possible.

Such MEMS switches can be manufactured on glass substrates, sapphire substrates and/or semiconductor substrates (what are known as wafers), for example from silicon or gallium arsenide. The length of a MEMS switching element is less than 1 mm, e.g. less than 500 μm. Here, the largest structural element of a single MEMS switching element is typically the bending element. This bending element may be of elongate form, in order to enable a defined, resilient deflection in the manner of a rectilinear leaf spring. The bending element is therefore often also referred to as a bending beam or as a switching tongue among experts. However, in principle, other forms and proportions are also possible.

Producing the bending element as a freed subregion of the semiconductor layer (which lies at the top in the layer system) has the effect that the switching properties of the bending element can be set particularly precisely, similarly to in the case of the conventional SOI MEMS switching elements.

The bending element is located in a superordinate hollow space of the component, which is composed of two areal substrates, namely the multi-layer carrier substrate and the cover substrate. In a horizontal orientation, this hollow space is delimited toward the “top” (on the side of the semiconductor layer, that is to say the third layer of the carrier substrate) by the cover substrate. Due to the external surface of the cover substrate, the hollow space is hermetically encapsulated toward the environment at the top. Similarly, the hollow space is encapsulated toward the external environment toward the “bottom” (toward the opposite side) by the carrier layer. To this end, the carrier layer is in particular of continuous full-area form on the bottom outer side thereof and comprises no continuous holes toward the external environment at least in the region of the hollow space. Furthermore, the multi-layer carrier substrate and the cover substrate are connected to one another such that here a hermetic encapsulation of the hollow space toward the outside is also produced so as to run in encircling fashion around the hollow space.

The movement of the bending element is enabled on the side of the carrier substrate in particular due to the fact that the carrier substrate comprises a cutout in the region of the bending element. This cutout is not continuous (that is to say does not pass through the entire carrier layer), but rather constitutes only a partial cavity. This partial cavity is thus a kind of flat blind hole and not a hole which is continuous toward the outside. In other words, the carrier layer in the region of the hollow space is only of thinner design than in the surrounding regions, and it is still of full-area form on the outer side.

Here, in contrast to the conventional SOI MEMS switching elements, a hermetic encapsulation of the active region of the switching element is thus obtained overall by the connection of only two substrates, namely the multi-layer carrier substrate and the cover substrate. An additional housing or another (third) substrate is not required for this hermetic encapsulation, but rather the encapsulation is already achieved by two substrates connected areally at the wafer level. This makes it possible for the entire construction to be implemented in a particularly compact manner.

An example apparatus incorporating teachings of the present disclosure comprises a switching element or an array of multiple such switching elements as described herein as sub-element(s). Irrespective of the special application purpose of the apparatus, the features thereof arise analogously to the above-described features of the switching element, in particular with regard to protection against environmental influences, a compact embodiment and/or a precise setting of the desired switching properties.

An example method incorporating teachings of the present disclosure serves to produce a switching element as described herein. In said method,
a) a prefabricated multi-layer carrier substrate with a prefabricated cavity in the carrier layer is provided,
b) the bending element is freed from this prefabricated carrier substrate by subtractive manufacturing, and,
c) in a wafer bonding step, the cover substrate is permanently connected to the carrier substrate, as a result of which the superordinate hollow space is hermetically encapsulated.

The described “freeing” of the bending element means that, at least over a predominant part of the longitudinal extent of the bending element, those regions of the semiconductor layer which adjoin said bending element are removed.

As described above, the prefabricated cavity in the first carrier layer should be a partial cavity, that is to say a hole which does not pass through to the opposite side. In the prefabricated carrier substrate, an areally continuous semiconductor layer is arranged in particular above this prefabricated cavity. The bending element is then freed from this areally continuous semiconductor layer, it being necessary overall to process the multi-layer carrier substrate only from the top side (the side of the semiconductor layer) and not from the rear side. Such prefabricated carrier substrates comprising buried partial cavities in the carrier layer are known. Numerous manufacturers offer these as a special variant of the SOI substrates under the designation C-SOI substrates (cavity silicon-on-insulator substrates). For the production of arrays comprising a multiplicity of MEMS switching elements, it is correspondingly also possible to use C-SOI substrates with a multiplicity of such cavities, at least one freed bending element then in particular being assigned to each cavity.

On account of the prefabricated cavity, the bending element is thus already exposed toward the bottom side prior to step b), since the cavity already forms part of the superordinate hollow space required for the deflection. The hermetic encapsulation of the superordinate hollow space formed overall is then achieved in step c) by the connection of the carrier substrate to the cover substrate by means of a wafer bonding step. The method thus makes it possible for the switching elements described herein to be produced in a particularly simple manner, wherein the already described advantages in relation to the encapsulation and the compact embodiment are implemented. In optional further steps (e.g. before or after step b), further elements may also be applied, and possibly structured, by surface micromachining techniques.

The deflection direction of the bending element may be oriented substantially perpendicularly with respect to the layer plane of the multi-layer carrier substrate. In other words, the bending element can be deflectable toward the “top” and “bottom” in the case of a horizontal orientation of the component of overall areal form. Such a movability out of the layer plane of the bending element can be implemented in a particularly simple manner with a bending element of leaf-spring-like form. Thus, it is then possible for the bending element to be deflected either in the direction of the cutout in the carrier layer or in the opposite direction, in the direction of the cutout in the cover substrate or of the cavity formed by the encircling spacer layer.

The multi-layer carrier substrate is a silicon-on-insulator layer system or comprises such a layer system. A silicon-on-insulator (abbreviated to: SOI) layer system comprises, in particular, a silicon-insulator-silicon layer sequence, wherein the carrier layer (the first layer of the layer system) is formed by the lower silicon layer, the second layer is formed by the insulator and the third layer is formed by the upper silicon layer. One of the two silicon layers or both silicon layers may be monocrystalline silicon.

In some embodiments, the insulator layer may be formed substantially by a silicon dioxide layer (SiO₂). It may be implemented in particular as what is known as a buried oxide layer (or BOX layer for short). SOI technology enables a particularly precise definition of the layer thicknesses and of the other material properties of the individual layers. The semiconductor layer from which the bending element is freed is in particular the thinner of the two silicon layers of a typical SOI substrate. The mechanical connection of the bending element to the other regions of the component may be mediated in particular by way of the insulator layer of the SOI substrate. In other words, the bending element may be coupled, in the foot region thereof, to a mechanically load-bearing part of the switching element by way of the insulator layer. These and further advantageous features and embodiment variants of the SOI layer system and the processing thereof are described in more detail in DE102017215236A1, which is therefore intended to be incorporated in its entirety into the disclosure of the present application.

In some embodiments, the carrier layer may alternatively be formed, for example, by a sapphire layer.

In some embodiments, the cutout in the carrier substrate comprises a cutout in the carrier layer, and this is formed by a prefabricated cavity in the SOI layer system. In other words, the switching element is constructed on a cavity SOI wafer (abbreviated to: C-SOI wafer). In some embodiments, this prefabricated cutout is a partial cavity in the lower silicon layer, and the buried oxide layer is also interrupted in this region. In some embodiments, it may alternatively be a partial cavity, in the lower silicon layer, which is lined in the base region with a corresponding oxide layer. Both types of C-SOI substrates are suitable, with comparatively little outlay in terms of processes, for providing the required superordinate hollow space for the movement of the bending element and for nevertheless enabling a hermetic encapsulation toward the bottom within the wafer layer system.

However, the use of a C-SOI substrate with a prefabricated cavity is not imperative. It is alternatively also possible for the partial cavity to be generated in the carrier substrate only during the production process for the switching element. In particular, in this case, the cavity may be limited to the insulating second layer, and the carrier layer may be maintained in its full thickness. Such a hole in the second layer (that is to say the buried oxide layer) may be formed, for example, by hydrogen fluoride etching. The cavity for the movement of the bending element is then correspondingly limited to the thickness of the oxide layer and possibly less deep. However, this may also be sufficient for the vertical movement required during the switching process, particularly if the opposite hollow space in the region of the cover substrate is comparatively deeper.

It is generally possible for the hermetic encapsulation of the superordinate hollow space to be effected in a lateral direction by a permanent, fluid-tight, areal connection between the multi-layer carrier substrate and the cover substrate. In other words, these two substrates may be connected by what is known as a “wafer bond”. This permanent connection can in particular be implemented so as to run in encircling fashion around the superordinate hollow space, such that the hollow space overall is hermetically encapsulated toward the outside. Numerous methods for such a wafer bonding step are known from the prior art. It is for example possible to use a gold-silicon bond or a germanium-aluminum bond or another type of eutectic bond. In some embodiments, the areal connection may also be implemented by a glass frit, by an anodic bond, by thermocompression bonding, by adhesive bonding and/or by fusion bonding.

In some embodiments, the cover substrate may be configured functionally as electrically insulating cover substrate and in particular be formed substantially from glass or silicon. This should be understood to mean that the glass or silicon forms the main constituent of the cover substrate and additional elements, in particular in the form of local coatings, should not be ruled out. It is in particular possible for a control electrode and additional contact elements to be applied as further elements to the surface of the cover substrate. In particular, control electrodes and/or contact element(s) may be arranged on that side of the cover substrate which faces the bending element. However, it is also possible for there to be e.g. metalizations in the form of line elements and/or contact elements and/or other structural elements on the outer side of the cover substrate.

Between the two main surfaces of the cover substrate, electrical leadthroughs may be provided, in particular in the form of what are known as vias, which extend through the substrate perpendicularly with respect to the substrate surface in order to electrically connect elements on the top and bottom side. In some embodiments, it is also possible to use a cover substrate composed of a conductive material which is coated on the side facing the bending element with an electrically insulating layer, such that an electrically insulating cover substrate is formed in a purely functional manner. Such an electrically insulating layer may be, for example, a silicon dioxide layer or a polymer layer.

In some embodiments, a switching contact may be arranged on the bending element. This switching contact may be formed, for example, by a structured metalization on the bending element. In some embodiments, it is possible for the bending element to bear further functional elements, and thus it does not have to consist only of the mentioned semiconductor layer.

In some embodiments, the cover substrate may bear a first mating contact which is able to be contacted with the switching contact of the bending element in dependence on a deflection of the bending element. It is thus possible, if the bending element is deflected toward the cover substrate and is in contact therewith in the end region thereof, for electrical contact between the switching contact of the bending element and a mating contact arranged opposite on the cover substrate to be mediated. In some embodiments, the cover substrate even bears a pair of mating contacts, which can both be contacted with the switching contact of the bending element. In this way, in the position deflected toward the cover substrate, the pair of mating contacts are thus electrically connected to one another. These two mating contacts may be configured as what is known as load contacts of a first load switching circuit. It is thus possible for the load switching circuit to be closed by means of the switching contact, and the switching element is in an “ON” position here. If the switching contact and the mating contact(s) are not connected, the switching element is in an “OFF” position.

In some embodiments, the cover substrate may comprise a control electrode which can be used to influence the deflection of the bending element. This control electrode is expediently placed over the bending element, and the switching voltage can be applied thereto during operation. In the prior art, such a control electrode is sometimes also referred to as a gate electrode. The bending element can be deflected by electrostatic interaction between the control electrode and the bending element. For example, it may be moved in the direction of the cover substrate on account of electrostatic attraction, such that electrical contact between a contact element of the bending beam and a contact element of the cover substrate is formed during this deflection.

In some embodiments, the superordinate apparatus may comprise an array of multiple switching elements as described herein. Such an array may be a parallel connection and/or a series connection of multiple such switching elements. A parallel connection of multiple switching elements may serve to increase the current carrying capacity of the entire apparatus in comparison with an individual switching element. A series connection of multiple switching elements may serve, in particular, to increase the dielectric strength in comparison with an individual switching element. In this way, the use of an array may contribute to the apparatus meeting the specification of a circuit breaker of an electrical energy distributor line—in particular in a low-voltage or medium-voltage power supply system. Here, the number of individual switching elements in the array may be aligned with the respective specifications. It may for example be in the range of a few 10s to a few 1000s of switching elements and even several hundreds of thousands for higher power ranges.

In some embodiments, the apparatus may comprise, in addition to the at least one switching element, one or more semiconductor elements which are electrically connected thereto in series or in parallel. These may be, for example, transistors or other semiconductor switching elements, as described in WO2018028947A1. The additional semiconductor elements can fundamentally be manufactured on the same substrate as the bending element, that is to say be monolithically integrated, or they can, in principle, also be manufactured on a different substrate and only subsequently be connected to the switching element.

The superordinate apparatus may be designed for use in entirely different applications. It may be configured, for example, as a switching device or switching contactor, as a converter or as an inverter, as a logic circuit and/or as a logic gate. The switching device or switching contactor may in particular be a device for a low-voltage or medium-voltage power supply system. The apparatus may generally also be a programmable logic controller, in particular a controller for an industrial plant. In this case, switching elements according to the invention may be used in an input stage, in an output stage and/or in a safety relay of such a plant controller.

In some embodiments, the apparatus is configured as a surface-mountable component. In other words, it may be an SMD or SMT component (SMD standing for “surface-mounted device” and SMT standing for “surface-mounting technology”). To this end, the apparatus may be provided, in the region of at least one of the substrate outer sides thereof, with solderable, areal SMD contact points.

In some embodiments, the cover substrate and/or the carrier substrate to comprise one or more leadthroughs for electrical contacting of the at least one switching element. In other words, it is possible for what are known as “vias” to be provided, which extend through the respective substrate perpendicularly with respect to the substrate surface in order to electrically connect elements on the top and bottom side. In particular, such vias are designed such that they do not break the hermetic encapsulation of the superordinate hollow space. Different methods by which such vias can be routed for example through a glass or semiconductor substrate while maintaining a hermetic encapsulation are known from the prior art.

In some embodiments, the bending element may be obtained from a silicon-on-insulator layer system by subtractive manufacturing, as already described further above for the corresponding embodiment of the switching element. In particular, the bending element may be formed by freeing part of a silicon layer of the SOI layer system. The production method may comprise a multiplicity of further optional manufacturing steps, which are fundamentally known in particular from MEMS and semiconductor processing. Provision may for example be made of additional metalization steps, e.g. in the form of a coating by vapor deposition, sputtering or galvanic deposition. The metallic layers for the electrodes and/or contact elements may comprise, for example, gold, chromium or silver or other standard metals in semiconductor manufacturing, and also metals and in particular noble metals which are rather unconventional in semiconductor manufacturing. The (complete or partial) removal of individual layers may be effected, for example, by etching and/or mechanical/chemical polishing and/or by a lift-off process. Use may especially be made of etching processes such as chemical etching with hydrofluoric acid and reactive ion etching (RIE, or DRIE standing for “deep reactive ion etching”) for defined removal of (partial) layers. In this case, precise structuring may be achieved by conventional lithographic structuring methods.

In some embodiments, the subtractive manufacturing of the bending element in step b) is effected by processing the multi-layer carrier substrate exclusively on one side. In some embodiments, only one-sided processing of a prefabricated carrier substrate is effected. In other words, processing in the region of the rear side is avoided here. This affords the damage in the region of the top semiconductor layer (that is to say the third layer of the multi-layer carrier substrate) can be avoided. This exclusively one-sided processing is enabled in particular by the use of prefabricated C-SOI substrates, since these make it possible to provide a sufficiently large cavity for the movement of the bending element without etching of the rear side.

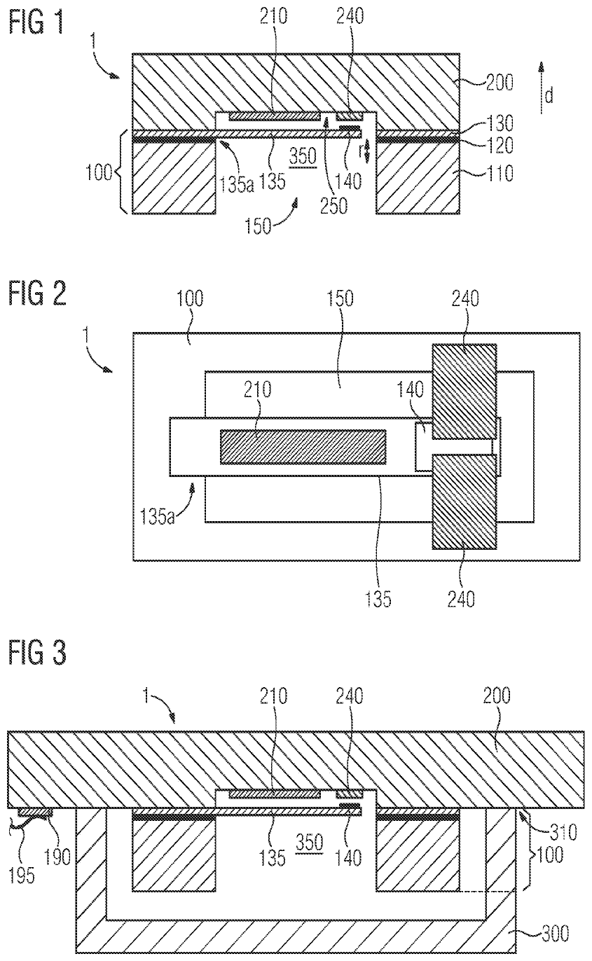

FIG. 1 shows a microelectromechanical switching element 1 known from the prior art. This switching element is of overall similar construction to that described in DE 10 2017 215 236 A1, but is illustrated in a somewhat simplified form here for the sake of clarity. The switching element comprises a silicon-on-insulator layer system 100, which here comprises a first silicon layer 110, then a buried oxide layer 120 and then a further silicon layer 130. The layer 130 may additionally also be followed by a second oxide layer as part of the SOI layer system 100 or such a second oxide layer may be present here at least during production. A bending element 135 has been defined and freed from the top semiconductor layer 130 by subtractive manufacturing. The production of the bending element in this case comprises the removal of the surrounding regions of the silicon layer 130 and the local removal of those parts of the layers 110 and 120 which adjoin the bending element 135. A bending element 135 which is deflectable in the thickness direction d has been generated here, similar to that described in DE 10 2017 215 236 A1. The other manufacturing steps may also be carried out analogously to DE 10 2017 215 236 A1. The foot region 135a of the bending element, in which the latter is mechanically connected to the other parts of the SOI layer system, is formed or shown in a somewhat simplified form here. As an alternative to this simpler implementation, the foot region 135a may alternatively be designed analogously to DE 10 2017 215 236 A1 or the as yet unpublished European patent application 20182568.4.

Toward the top, the component is covered by a cover substrate 200, which may be formed, for example, from glass. It is for example possible for this cover substrate 200 to have been connected to the SOI layer system 100 by a wafer bonding step. The cover substrate comprises a cutout 250 in the region of the bending beam, such that, together with the opening 150 in the layers 110 and 120, a superordinate hollow space 350 is formed, in which the bending element 135 can be deflected. In this case, the carrier layer 110 has been completely etched away from the substrate bottom side in the region of the opening 150, such that the bending element is freely accessible here from the side illustrated at the bottom.

In order to bring about the deflection of the bending element, a control electrode 210 is provided on the cover substrate 200 in the region above the bending element 135. Applying a voltage to the control electrode 210 makes it possible to electrostatically actuate a deflection of the bending element. If the bending element 135 is deflected upward in the direction d, the end region thereof may be brought into contact with the cover substrate to such an extent that a switching contact 140 applied to the bending element 135 and a mating contact 240 applied in the cutout in the cover substrate 200 connect electrically. In this way, the switching element can be switched to “ON”, and an associated load current circuit can be closed by the switching element 1.

The switching element 1 shown may be part of a superordinate apparatus, which may in particular comprise an array of switching elements which are similar to one another. Such a MEMS array may be constructed monolithically from the same SOI substrate. In this case, the region shown in FIG. 1 should be understood to be a detail of a larger component, the lateral layers extending further to the right and left (and of course also perpendicular to the plane of the paper) and further similarly constructed switching elements being able to be comprised in these spatial directions.

FIG. 2 shows a schematic top view of such a conventional switching element, which, with respect to the layer sequence thereof, may be constructed in particular similarly to the switching element in FIG. 1. Here, however, the deflection direction r lies perpendicular to the plane of the drawing, and both elements of the SOI substrate 100 and elements of the cover substrate 200 are depicted lying one above the other. The metalizations of the control electrode 210 and of the two mating contacts 240, said metalizations being arranged on the cover substrate 200, in this case partially conceal the layers lying thereunder.

In the foot region 135a of the bending element, the latter is connected to the other layers of the SOI layer system 100 and connected to the cover substrate 200 by way of the areal wafer bond. In the middle region, the bending element interacts electrostatically with the control electrode 210 lying thereabove on the cover substrate, particularly if a switching voltage is applied to said control electrode. In the end region, the bending element bears a switching contact 140. Located opposite thereto in this example on the cover substrate is a pair of mating contacts 240 lying next to one another. In the event of deflection of the bending element, these two contacts 240 are electrically connected to the switching contact 140 of the bending element and also to one another by way of said switching contact, and the switching element is then in an ON position. By contrast, the basic position illustrated in FIG. 1 with a non-deflected bending element corresponds to the OFF position of the switching element.

FIG. 3 shows a similar conventional switching element, which, however, in contrast to the switching element in FIG. 1, is hermetically encapsulated by a housing, as a result of which in particular the region of the switching element 135 is protected against external environmental influences. The inner construction is analogous to FIG. 1 overall, but with the cover substrate 200 being larger in the lateral direction than the SOI substrate and correspondingly protruding laterally beyond said SOI substrate. In this edge zone, the cover substrate 200 is connected to a cap-like housing cover 300, which is configured for example as a glass cover, by an encircling connection 310.

The encircling connection 310 may be, for example, a hermetically sealed soldered or welded connection. In this example, the superordinate hollow space 350, in which the bending element moves, is hermetically sealed overall in relation to the external environment, specifically toward the top by the cover substrate 200 and toward the bottom by the housing cover 300. The switching element 1 is thus protected overall against damage due to external environmental influences.

However, the structure with the two substrates 100, 200 and the housing cover 300 is comparatively bulky both in the thickness direction and laterally owing to the wide encircling edge. In the edge region, contact points 190 for bonding wires 195 may be provided in addition to the housing cover, said contact points also taking up further space. Only one such bonding pad 190 is shown here by way of example. It may be connected to one of the electrodes of the switching element (e.g. 210, 240) by a connecting line (not shown in any more detail here).

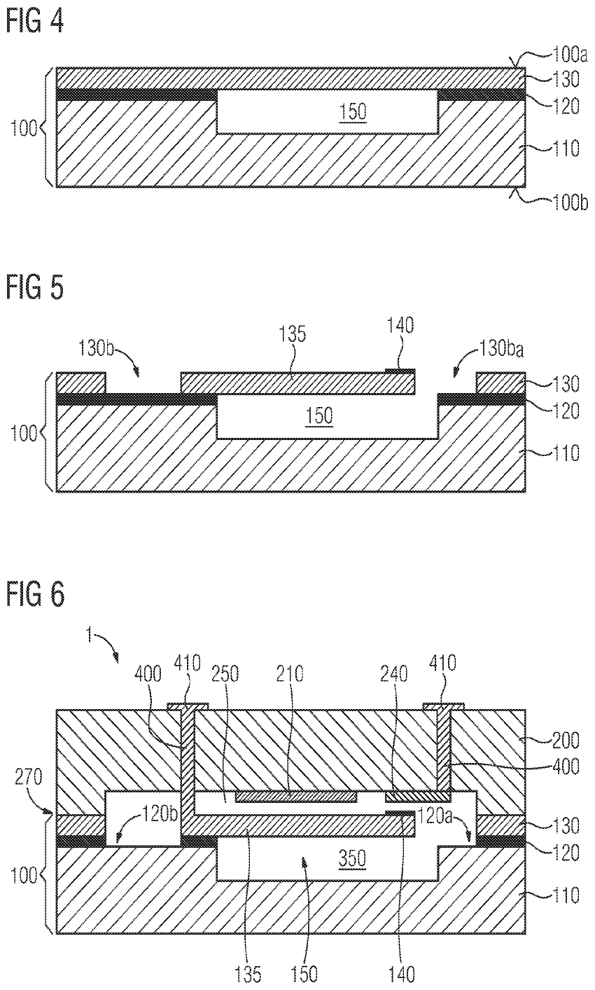

FIGS. 4 to 6 show a plurality of process stages in the production of a switching element 1 incorporating teachings of the present disclosure. FIG. 6 shows the substantially finished switching element 1 or a lateral detail of a corresponding apparatus comprising multiple such switching elements.

FIG. 4 shows a prefabricated multi-layer carrier substrate 100 which is used for the production of this switching element. Here, this prefabricated carrier substrate 100 is also an SOI substrate comprising a carrier layer 110 composed of silicon, an electrically insulating layer 120 composed of a buried silicon oxide and a top third layer 130, which is also a silicon layer. A prefabricated cavity 150 lies in the interior of this layer construction and constitutes a cutout in the oxide layer 120 and in part of the carrier layer 110. However, this cavity 150 is only a partial cavity; it is in particular not open toward the bottom side 100b of the carrier substrate, but rather the carrier layer 110 still forms a continuous areal layer on the bottom side 100b.

By contrast, on the top side 100a, this cavity 150 is delimited by the top semiconductor layer 130. This thus results in a closed internal hollow. Such prefabricated SOI substrates with buried cavities are well known from the prior art and are offered by numerous manufacturers under the designation C-SOI. In the lateral direction, it is also possible for multiple such buried cavities to be present next to one another, particularly if an array composed of multiple similar switching elements is intended to be produced. Each cavity 150 then contributes to forming the superordinate hollow space necessary for the movement of the respective bending element.

FIG. 5 shows a more advanced process stage, in which the carrier substrate 100 has already run through a plurality of process steps. The performance of these individual process steps can be developed in detail. The materials and thicknesses of the individual layers and further elements may also be selected. The processing can be effected only from the top side 100a, that is to say that no lithography or etching steps must be carried out on the bottom side 100b and the carrier substrate 100 must correspondingly be held only from this bottom side 100b during the processing. In this way, in comparison with a double-sided process, the top side 100a is protected against mechanical damage.

In the process stage in FIG. 5, a metallic switching contact 140 has been applied in a structured manner in the end region of the bending element 135. Furthermore, the upper semiconductor layer 130 has been opened in the regions 130a and 130b. In particular, these two openings 130a, 130b may in fact be a single opening in the layer 130, said opening running in encircling fashion around the bending element in a ring-like manner. In some embodiments, the layer 130 may alternatively be removed only in the middle region and in the end region of the bending element (corresponding to opening 130a), and the opening 130b in the foot region of the bending element may be omitted, such that the bending element, in the foot region, also remains connected to the rest of the layer stack by way of the layer 130 similarly to in FIG. 1. Different embodiments overall are conceivable for the configuration and mechanical coupling of the foot region. It is essential only that the bending element 135 is freed from the layer system 100 by subtractive manufacturing to such an extent that it is deflectable perpendicular to the layer plane. In the direction of the carrier layer, this deflection is enabled by the cavity 150 which is already present in the prefabricated layer system 100.

FIG. 6 shows the substantially completely processed switching element 1. In contrast to FIG. 5, here the oxide layer 120 in the regions 120a and 120b has also been removed in encircling fashion around the bending element. Subsequently, the layer system was connected on the substrate top side 100a to a cover substrate 200 by an encircling areal wafer bond connection 270, similarly to in the case of the conventional switching element in FIG. 1.

Overall, the cover substrate 200 is constructed similarly to in FIG. 1 and here also comprises a cutout 250 which forms, together with the already described cavity 150, the superordinate hollow space 350 for the movement of the bending element 135. The essential difference with respect to the conventional switching element in FIG. 1 is that the superordinate hollow space 350 is not exposed toward the substrate bottom side 100b, but rather is closed. In this way, the permanent areal connection between the carrier substrate 100 and the cover substrate 200 achieves a hermetic encapsulation of the hollow space 350, without an additional housing cover being necessary for this (as in FIG. 3). A very compact component can be implemented in a simple manner, said component nevertheless being robust with respect to external environmental influences since the region of the bending element is hermetically encapsulated toward the outside.

A further difference in the switching element in FIG. 6 with respect to the conventional component in FIG. 3 is that the electrical contacting here is not effected by wire bonds, but rather by vias 400 in the cover substrate and corresponding solderable contact points 410. In other words, it can be an SMD component. However, this additional difference is optional, and it would in principle also be possible for contacting via bonding wires similarly to in FIG. 3 to be implemented.

In some embodiments, the leadthroughs 400 may be routed through the carrier substrate 100 on the bottom side 100b or corresponding vias and contact points could be arranged both on the top side and on the bottom side. FIG. 6 shows merely by way of example a via 400 for the contacting of the bending element (for the electrical earthing thereof) and a further via 400 for the contacting of one of the mating contacts 240. It goes without saying that further elements, for example the control electrode 210 and the second mating contact which is not visible here, may also be contacted in a corresponding manner.

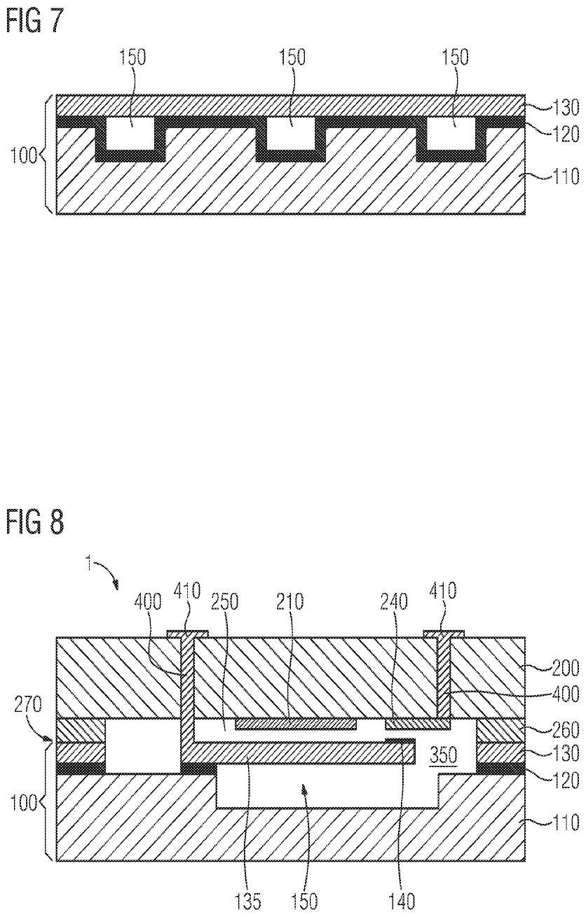

FIG. 7 shows a further prefabricated carrier substrate 100 for producing a switching element incorporating teachings of the present disclosure. In contrast to the carrier substrate in FIG. 4, this carrier substrate comprises not only one cavity but an array of multiple buried cavities 150 lying next to one another. In other words, an apparatus comprising an array of multiple switching elements can be produced therefrom. A further difference is that the respective cavity is lined with an oxide layer in the base region. In other words, the oxide layer 120 is not interrupted here, but is laid only locally in the base of the individual cavities 150. This variant of a C-SOI substrate is also commercially available from various manufacturers and can otherwise be used in a similar manner to the substrate in FIG. 4 for producing a switching element according to the invention.

FIG. 8 shows another example switching element 1 incorporating teachings of the present disclosure. Overall this switching element 1 is constructed similarly to in the case of the example in FIG. 6. However, one difference is that the cover substrate does not comprise a hollow-like cutout in its basic material (e.g. in the glass), but rather that the corresponding hollow space is formed here by a spacer layer 260 running in encircling fashion around the region of the bending element. However, a cutout 250 in the cover substrate is, in turn, effectively formed by the open region within this encircling spacer layer 260, said cutout forming, together with the opposite cutout in the carrier substrate, the superordinate hollow space 350 for the bending element. Otherwise, the switching element in FIG. 8 has been constructed analogously to the example in FIG. 6 and may advantageously also have been produced in an analogous manner with a prefabricated C-SOI substrate.

### LIST OF REFERENCE DESIGNATIONS

1 MEMS switching element
100 Multi-layer carrier substrate (SOI substrate)
100a Substrate top side (front side)
100b Substrate bottom side (rear side)
110 First layer (carrier layer)
120 Second layer (buried oxide)
120a Opening in the second layer
120b Opening in the second layer
130 Third layer (semiconductor layer)
130a Opening in the third layer
130b Opening in the third layer
135 Bending element
135a Foot region
140 Switching contact
150 Cutout (cavity) or opening
190 Contact point
195 Bonding wire
200 Cover substrate
210 Control electrode
240 Mating contact
250 Cutout
260 Encircling spacer layer
270 Connection (wafer bond)
300 Housing cover
310 Connection
350 Superordinate hollow space
400 Leadthrough (via)
410 Contact point
d Thickness direction
r Deflection direction

What is claimed is:

1. A microelectromechanical switching element comprising:
a carrier substrate with a carrier layer, an electrically insulating layer, and a semiconductor layer;
a deflectable bending element formed by a freed subregion of the semiconductor layer;
and
an cover substrate connected to the carrier substrate;
wherein the carrier layer defines a first cutout in the region of the bending element; and
the cover substrate comprises a second cutout and/or an encircling spacer layer in the region of the bending element;
the first cutout and the second cutout define superordinate hollow space in which the bending element is arranged so as to be deflectable;
the superordinate hollow space is delimited by the carrier layer and by the cover substrate to provide a hermetically encapsulation from the external environment; and
the carrier substrate comprises a silicon-on-insulator layer system.

2. The switching element as claimed in claim 1, wherein a deflection direction of the bending element is oriented perpendicularly with respect to the layer plane of the carrier substrate.

3. The switching element as claimed in claim 1, wherein the cutout in the carrier layer is formed by a prefabricated cavity in the silicon-on-insulator layer system.

4. The switching element as claimed in claim 1, wherein the hermetic encapsulation of the superordinate hollow space includes a permanent, fluid-tight, areal connection between the carrier substrate and the cover substrate.

5. The switching element as claimed in claim 1, wherein the cover substrate comprises an electrically insulating cover substrate comprising glass or silicon.

6. The switching element as claimed in claim 1, wherein:
a switching contact is arranged on the bending element; and
the cover substrate bears at least one mating contact which is able to be contacted with the switching contact of the bending element by a deflection of the bending element.

7. The switching element as claimed in claim 1, wherein the cover substrate comprises a control electrode to influence the deflection of the bending element.

8. An apparatus comprising:
an array of multiple microelectromechanical switching elements, wherein each microelectromechanical switching element comprises:
a carrier substrate with a carrier layer, an electrically insulating layer, and a semiconductor layer;
deflectable bending element formed by a freed subregion of the semiconductor layer; and
an cover substrate connected to the carrier substrate;
wherein the carrier layer defines a first cutout in the region of the bending element; and
the cover substrate comprises second cutout and/or an encircling spacer layer in the region of the bending element;
the first cutout and the second cutout define a superordinate hollow space in which the bending element is arranged so as to be deflectable;
the superordinate hollow space is delimited by the carrier layer and by the cover substrate to a hermetically encapsulation from the external environment; and
the carrier substrate comprises a silicon-on-insulator layer system.

9. The apparatus as claimed in claim 8, comprising a switching apparatus, converter or inverter, a logic circuit and/or a logic gate.

10. The apparatus as claimed in claim 8, comprising a surface-mountable component.

11. The apparatus as claimed in claim 8, wherein the cover substrate and/or the carrier substrate comprises one or more leadthroughs for electrical contacting of the at least one switching element.

12. A method for producing a switching element, the method comprising:
applying a prefabricated multi-layer carrier substrate with a prefabricated cavity in the first carrier layer;
freeing the bending element the prefabricated carrier substrate by subtractive manufacturing; and
permanently connecting the cover substrate to the carrier substrate in a water bonding step;
wherein the superordinate hollow space is hermetically encapsulated; and
wherein the multi-layer carrier substrate is a silicon-on-insulator layer system.

13. The method as claimed in claim 12, wherein the subtractive manufacturing includes processing the multi-layer carrier substrate exclusively on one side.
